(19) United States
(12) Patent Application Publication
(10) Pub. No.: US 2023/0327400 A1
(43) Pub. Date: Oct. 12, 2023

(54) PHOTOCONDUCTIVE SEMICONDUCTOR LASER DIODES AND LEDS

(71) Applicant: Lawrence Livermore National Security, LLC, Livermore, CA (US)

(72) Inventors: Lars Voss, Livermore, CA (US); Adam Conway, Livermore, CA (US); Selim Elhadj, Livermore, CA (US); Vincenzo Lordi, Livermore, CA (US); Joel Basile Varley, Livermore, CA (US)

(21) Appl. No.: 17/658,996

(22) Filed: Apr. 12, 2022

(51) Int. Cl. H01S 5/04; H01S 5/343; H01S 5/30

(52) U.S. Cl. CPC H01S 5/041; H01S 5/34333; H01S 5/3063; H01S 5/22

(57) ABSTRACT

Ultraviolet light sources such as UV and DUV laser diodes and light emitting diodes (LEDs) are described. The UV light source may comprise at least one quantum well with first and second photoconductive layers on opposite sides thereof. The UV light source may further comprise at least one optical pump configured to direct pump light to the UV light emitter. The pump light may have a photon energy less than the band gap of the at least one quantum well to increase the conductivity of electrons and holes in the first and second photoconductive layers. The electrons and holes can thereby propagate to the quantum well where at least some of the electrons and holes combine resulting in the emission of UV light.

### FEDERALLY SPONSORED RESEARCH OR DEVELOPMENT

This invention was made with Government support under Contract No. DE-AC52-07NA27344 awarded by the United States Department of Energy. The Government has certain rights in the invention.

### BACKGROUND

### Field

The present disclosure relates generally to ultraviolet (UV) light sources and more specifically to deep ultraviolet (DUV) light sources such as laser diodes and light emitting diodes (LEDs) as well as devices, systems and methods related thereto.

### Description of the Related Art

Ultraviolet (UV) and deep ultraviolet (DUV) light emitting diodes (LEDs) and laser diodes based on the III-Nitride materials, compounds comprising an element from column III of the periodic table and nitrogen (typically, e.g., alloys of Al(Ga,In)N) have been the subject of interest due to the lack of semiconductor lasers at in this wavelength region. Electrically pumped ultraviolet LEDs and laser diodes generally suffer from low output power and efficiency, especially for wavelengths deeper into the UV. Electrically pumped lasers based on AlN, AlGaN, or AlInGaN may be limited due to the lack of suitable shallow donor and acceptor dopants. As the band gap of these materials increases (and the emission wavelength decreases), both electrons and holes require greater thermal energies in order to ionize, which reduces the availability of such carriers thereby limiting optical output.

Some reports of optically pumped DUV laser diodes rely on excitation with above band gap light using relatively large lasers, such as excimer systems, emitting at wavelengths such as 193 nm. While possibly useful for research, this approach may not be a practical solution for adoption of UV LEDs and laser diodes.

### SUMMARY

Disclosed herein are examples of ultraviolet and deep ultraviolet light sources such as UV and DUV laser diodes and LEDs. Various devices, systems, and methods described herein, for example, use photoconductive material for providing electrons and holes that can be combined in a quantum well to generate UV radiation. In some implementations, an optical pump directs light (e.g., infrared light) onto the photoconductive material to create excited electrons and holes that can travel to the quantum well to produce UV light.

In one design, for example, a light source for emitting ultraviolet (UV) light comprises a UV light emitter and at least one optical pump configured to direct pump light to the UV light emitter. (The pump light from the optical pump has an energy less than the bandgap of the quantum well.) The UV light emitter comprises a first photoconductive layer, at least one quantum well having a band gap configured to emit ultraviolet light; and a second photoconductive layer. The pump light is configured to increase the conductivity of electrons and holes in the first and second photoconductive layers such that the electrons and holes propagate to the quantum well resulting in the emission of UV light. In various implementations, at least some of the electrons and holes combine in the quantum well to produce UV light.

In certain implementations, the light source may comprise a laser diode or an LED. The quantum well may comprise a multiple quantum well. The first photoconductive layer, the second photoconductive layer, or both may comprise aluminum nitride (AlN). For example, the first photoconductive layer may comprises aluminum nitride (AlN) doped with silicon (Si), and the second photoconductive layer may comprise aluminum nitride (AlN) doped with magnesium (Mg). The quantum well may comprise aluminum gallium nitride in some implementations. The at least one optical pump may comprise an infrared pump such as an infrared laser (e.g., an infrared laser diode).

In another example design, a light source for emitting ultraviolet (UV) light also comprises a UV light emitter and at least one optical pump. The UV light emitter comprises a first photoconductive layer, a second photoconductive layer, and at least one quantum well, which may be disposed therebetween. The first photoconductive layer comprises semiconductor doped such that electrons are excited into a conduction band when exposed to pump light (e.g. infrared light), and the second photoconductive layer comprises semiconductor doped such that holes are excited into the valence band when exposed to pump light (e.g., infrared light). The at least one quantum well is configured to emit ultraviolet light when electrons and hole combine therein. The at least one optical pump is configured to direct light to the UV light emitter such that electrons and holes are excited into the conduction band and the valence band, respectively, and at least some of the electrons and holes travel to the quantum well and combine thereby producing UV light emission.

By using sub-band gap (e.g., infrared) light of sufficient energy to excite electrons and holes from relatively deep donor and acceptor levels in the n-type and p-type photoconductive layers, respectively, the conductivity of these layers can be effectively increased, possibly by orders of magnitude, and both electrons and holes can be injected into the quantum well(s) of the device, resulting in light emission.

### BRIEF DESCRIPTION OF THE DRAWINGS

The drawings described herein are for illustrative purposes only of selected embodiments and not all possible implementations and are not intended to limit the scope of the present disclosure.

Corresponding reference numerals indicate corresponding parts throughout the several views of the drawings.

FIG. 1 is a band diagram of an example photoconductive light source comprising a quantum well configured to emit ultraviolet light sandwiched between a pair of photoconductive layers configured to excite electrons and holes from deep donor and acceptor states into the conduction and valence bands, respectively, upon being illuminated with light of sufficient energy (e.g., infrared light).

FIG. 2 is a schematic block diagram view of an example device or system configured to produce UV light comprising an optical pump such as an infrared pump (e.g., an infrared laser) and a UV light emitter comprising, for example, a quantum well sandwiched between photoconductive layers such as described herein. In various implementations, the UV light emitter comprises a diode comprising a quantum well having p-type and n-type photoconductors on opposite sides.

FIG. 3A is a schematic cross-sectional view of an example UV light emitter comprising a quantum well sandwiched between p-type and n-type photoconductors.

FIG. 3B is a schematic cross-sectional view of an example UV light emitter comprising a multiple quantum well sandwiched between p-type and n-type photoconductors.

FIG. 4A is a schematic cross-sectional view of the example UV light emitter shown in FIG. 3A comprising a quantum well sandwiched between p-type and n-type photoconductors. The cross-section shown in FIG. 4A is orthogonal to the cross-section shown in FIG. 3A.

FIG. 4B is a schematic cross-sectional view of the example UV light emitter shown in FIG. 3B comprising a multiple quantum well sandwiched between p-type and n-type photoconductors. The cross-section shown in FIG. 4B is orthogonal to the cross-section shown in FIG. 3B.

FIG. 5A is a schematic cross-sectional view of an example UV light emitter comprising a quantum well sandwiched between p-type and n-type photoconductors in a mesa formed on a semiconductor substrate.

FIG. 5B is a schematic cross-sectional view of an example UV light emitter comprising a multiple quantum well sandwiched between p-type and n-type photoconductors in a mesa formed on a semiconductor substrate.

FIG. 6 is a schematic cross-sectional view of an example UV light emitter comprising an AlₓGaₓ₋₁N quantum well sandwiched between p-type AlN:Mg and n-type AlN:Si photoconductors.

FIGS. 7A and 7B are top and cross-sectional views of a microdisc resonator including a UV light emitter comprising a quantum well sandwiched between p-type and n-type photoconductor layers.

### DETAILED DESCRIPTION

Systems and methods are described herein for producing ultra-violet or deep-ultraviolet lasers and LEDs. The laser diode and LED structures can include p- and n-type photoconductive layers that sandwich a single or multi quantum well structure and inject carriers into the quantum well(s). Acceptors and donors in the p- and n-type layers, respectively, are not considered shallow and only a small percentage ionized thermally or with electrical pumping. Accordingly, in various designs described herein, sub-band gap light of sufficient energy to promote electrons and holes into conduction and valence bands, respectively, is used to increase the conductivity of both the p- and n-type photoconductive regions. Both p- and n-type carriers (e.g., holes and electrons) then transport to the quantum well region and combine (e.g., recombine with each other), emitting light at the band gap of the quantum well. In some designed, the geometry of the device, e.g., laser diode, may be such that the incident sub-band gap light is trapped, facilitating high absorption, using various schemes such as total internal reflection or whispering gallery mode(s).

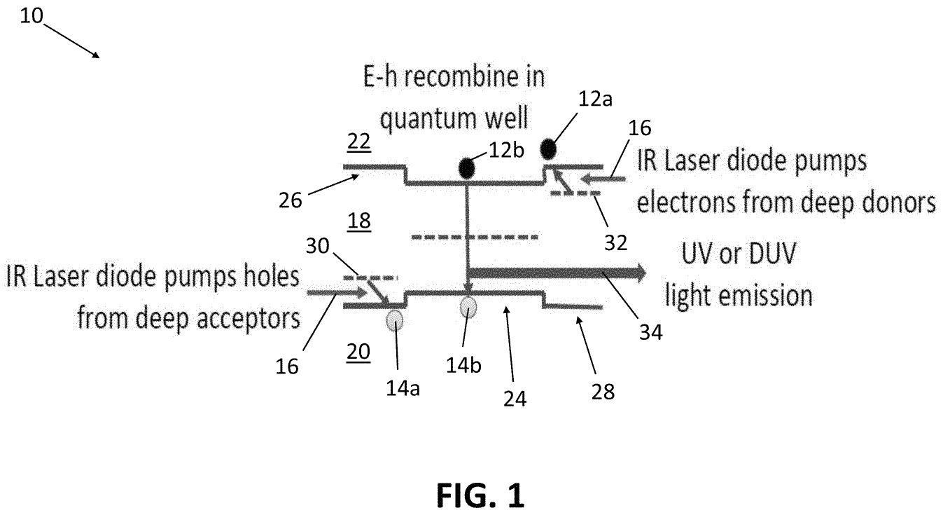

FIG. 1 shows a band diagram 10 of an example device to illustrate the process of producing UV light from electrons 12a, 12b and holes 14a, 14b excited by sub-band gap pump radiation 16. The band diagram 10 shows band gaps 18 separating valence bands 20 and conduction bands 22 in different portions of the device. The band diagram 10 also shows a quantum well 24 sandwiched between first and second photoconductive layers 26, 28. Deep acceptor states 30 and deep donor states 32 are shown in the band gaps 18 of the first and second photoconductive layers 26 and 28. These deep acceptor states 30 and deep donor states 32 may be sufficiently separated from the valence and conduction bands 20, 22, respectively such that holes 14a and electrons 12a are not easily excited into the valence and conduction band thermally or electrically. However, pump light 16 may excite holes 14a from the deep accepter states 30 into the valence band 20 and may excite electrons 12a from the deep donor states 32 into the conduction band 22. These holes 14a and electrons 12a, once excited into the valence band 20 and conduction band 22, respectively, can more freely travel or transport to the quantum well 24 and produce optical emission. These holes 14b and electrons 12b, once in the quantum well 24, for example, can combine radiating light 34 in the process.

For various devices described herein, the band gap 18 of the quantum well 24 is sufficiently large that ultraviolet light 34 is emitted when electrons 12b in the conduction band 22 combine with the holes 14b in the valence band 20. As illustrated in FIG. 1, the energy separation between the conduction band 22 and the valence band 20 in the quantum well 24 (e.g., the band gap) is larger than the energy separation of the acceptor states 30 and the valence band 20 in the first photoconductive layer 26 and larger than the energy separation of the deep donor states 32 and the conduction band 22 in the second photoconductive layer 28. Likewise, lower energy photons (longer wavelength pump light) 16 may be used to cause the holes 14a to transition from the donor states 30 to the valence band 20 in the first photoconductive layer 26 and to cause the electrons 12a to transition from the electron states 32 to the conduction band 22 in the second photoconductive layer 28. This pump light 16 may be lower energy (longer wavelength) than the photons or light 32 radiated from the quantum well, for example, upon combining of the electrons and holes 12b, 14b, in the quantum well 24 as the energy transitions from the acceptor and donor states 30, 32 to the respective valance band and conduction bands, are less than the energy difference between the valence and conduction bands (e.g., the potential difference of the band gap). The pump light 16 may for example comprise infrared (IR) light, while the light radiated from the quantum well(s), e.g., as a result of combining the electrons and holes 12b, 14b, in the quantum well(s) 24 may comprise UV light. This pump light 16 may therefore be referred to herein as sub-band gap light as the energy of the pump photons is less than the band gap or energy difference between the conduction band 22 and the valence band 20 in the quantum well(s) 24.

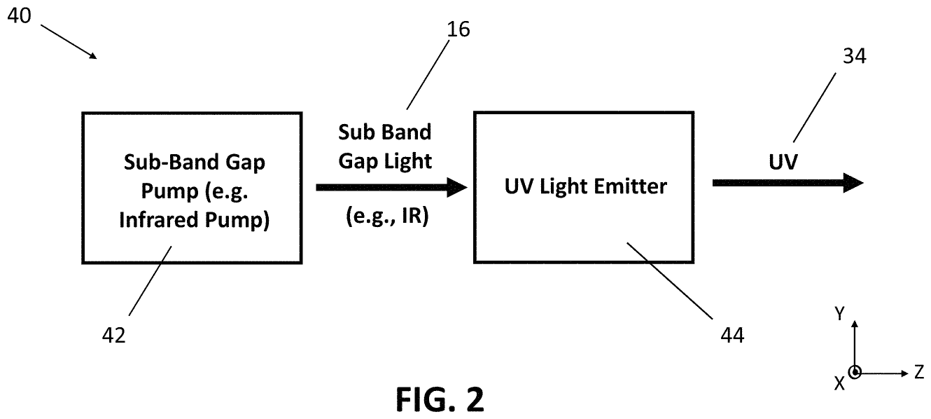

Since pump light 16 is employed to cause holes 14a to transition from deep acceptor states 30 into the valence band 20 and to cause electrons 12a to transition from deep donor states 32 into the conduction band 22, various devices and systems 40 such as shown in FIG. 2 comprise a sub-band gap optical pump such as an infrared pump 42 that outputs light that is directed to a UV light emitter 44. The optical pump 42 may comprise an infrared pump outputting pump light 16 having an infrared wavelength that is received by the UV light emitter 44. The optical pump 42 may comprise a laser diode in some implementations. A low energy laser diode emitting at an appropriate wavelength (e.g., infrared light) can be used to optically pump the UV photoconductive LED or laser diode 44. The energy need only be sufficient to ionize the electrons 12a and/or holes 14a. In some implementations, the optical pump 42 is configured to pump primarily holes (e.g., is configured to pump holes more than electrons) or only holes (in comparison to electrons), for example, in some design that employ AlN or AlGaN. In other implementations, the optical pump 42 is configured to pump primarily electrons (e.g., is configured to pump electrons more than holes) or only electrons (in comparison to holes). Accordingly, the optical pump 42 can use significantly less energy to create a photon than, for example, a pump such as a UV laser (e.g., an excimer laser) that outputs light having a photon energy that is at least the size of the band gap 18.

In various implementations, one or more optical pumps 42 may be employed to pump the UV emitter 44. For example, one or more laser diodes may be used to pump the UV light emitter 44. Advantageously, laser diodes can be highly efficient (e.g., more efficient than an excimer laser) and can have an energy per photon that is significantly smaller, for example, than an excimer laser. As discussed above, the optical pump 42 may comprise an infrared pump such as an infrared laser diode. However, the optical pump 42 may, in other implementations, comprise wavelengths other than infrared such as visible wavelengths. In various implementations, the wavelength of the optical pump 42 is longer than the wavelength of light 34 output by the light emitter 44 (e.g., UV light emitter emitting UV light).

As discussed above, for example, with reference to FIG. 1, the UV light emitter 44 may comprise a quantum well 24 that emits UV light 34 when electrons 12b and holes 14b are combined in the quantum well. The UV emitter 44 may also comprise a first photoconductive layer 26 and a second photoconductive layer 28. The first and second photoconductive layers 26, 28 are configured such the pump light 16 incident thereon increases the conductivity of electrons 12a and holes 14a in the first and second photoconductive layers. This increase in conductivity is sufficient to cause at least some of the electrons and holes 12a, 14a to propagate to the quantum well 24 and produce light (e.g., UV light) emission. At least some of the electrons 12b and holes 14b may, for example, combine in the quantum well resulting in the emission of UV light 34. Accordingly, either or both the first and second photoconductive layers 26, 28 may comprise semiconductor. In various implementations, the first photoconductive layers 26 has acceptor states sufficiently close to the valence band 20 such that pump light 16 has sufficient energy to cause holes 14a in the donor states 30 to transition to the valance band 20. Similarly, in various implementations, the second photoconductive layer 28 has donor states 32 sufficiently close to the conduction band 22 such that pump light 16 has sufficient energy to cause electrons 12a in the donor states to transition to the conduction band.

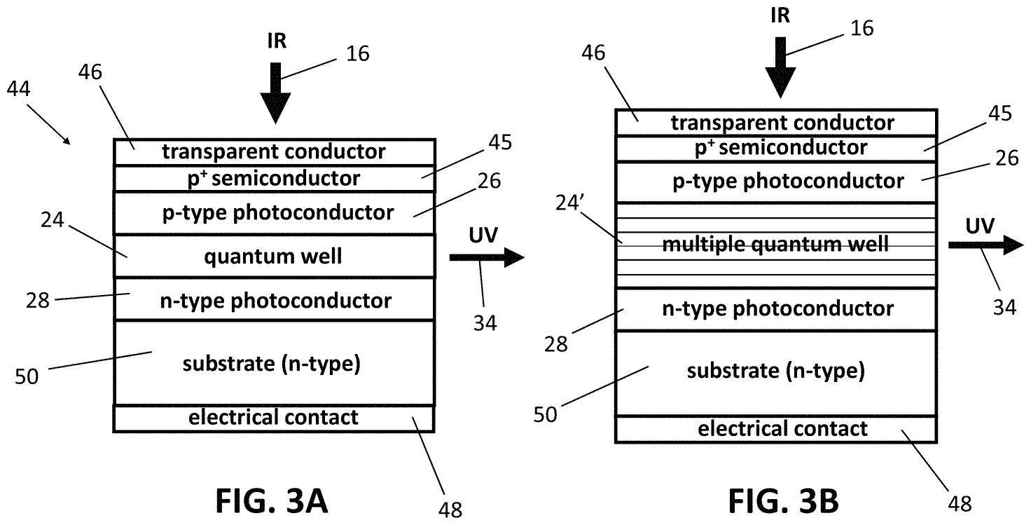

FIG. 3A shows an example UV light emitter 44 comprising a quantum well 24 between first and second photoconductor layers 26, 28. As discussed above, these photoconductors 26, 28 may comprise semiconductor such as doped semiconductor. FIG. 3A, for example, shows a p-type photoconductor 26 doped to provide holes 14a and an n-type photoconductor 28 doped to provide electrons 12a on opposite sides of the quantum well 24. As discussed above, the first photoconductive layer 26 may comprises semiconductor doped such that holes 14a are excited into a valence band 20 when exposed to pump light 16, which may comprise sub-band gap light (e.g., infrared light). Additionally, the second photoconductive layer 28 may comprise semiconductor doped such that electrons 12a that are excited into the conduction band 22 when exposed to sub-band gap light (e.g., infrared light) 16. Once in the valence band 20, at least some of the holes 12a can travel or transport to the quantum well 24 between a pair of photoconductors 26, 28. Once in the conduction band 22 at least some of the electrons 14a can travel or transport to the quantum well 24. Additionally, in various implementations, the holes and/or electrons transition to lower energy states producing the emission of light. For example, the holes and/or electrons transition across the band gap 18 of the quantum well 24 producing optical emission in the process. In various implementations, at least some of these electrons 12b and holes 14b combine in the quantum well 24, transitioning across the band gap 18 of the quantum well 24, causing the emission of UV light. In various implementations, the quantum well 24 comprises layers of the semiconductor comprising the p-type and n-type photoconductive layers such as semiconductors (e.g., AlN and AlGaN).

FIG. 3A also shows the UV light emitter 44 as comprising electrical contacts 46, 48 to apply electrical power to the UV light emitter, which may comprise a diode such as a laser diode or a light emitting diode in some implementations. At least one of the electrical contacts 46 in the design shown in FIG. 3A is transparent or optically transmissive to the pump light 16 such that the pump light can transmit through this contact and reach at least one of the photoconductor 26, 28 and possibly both of the photoconductors. In certain implementations, however, the other electrical contact 48 may be transparent or optically transmissive to pump light and a pump beam may be configured to pass therethrough to reach one or both of the p- and n- type photoconductive layers. In some implementations both electrical contacts 46, 48 may be transparent or optically transmissive to pump light and pump beams (possibly from two pump sources) may be configured to pass through the respective electrical contacts. Such light from either beam could possibly illuminate one or both of the p- and n- type photoconductive layers. With such configurations, light could possibly illuminate the p- and n- type photoconductive layers from opposite directions.

The transparent conductor 46 may comprise, for example indium tin oxide, aluminum zinc oxide, or graphene in some designs. However, other materials may be employed. In some implementations, the electrical contact 48 comprises metal or a metal stack and may form an Ohmic contact. Other conductive materials may also be used. Additionally other variations are possible. For example, the contact 48 closer to the n-type photoconductor 28 may be transparent or optically transmissive while the contact 46 closer to the p-type photoconductor 26 may not be transparent or optically transmissive and may comprise metal or a metal stack and may possibly form an Ohmic contact. Additionally, as discussed above, both contacts 46, 48 may be transparent or optically transmissive as discussed above. Accordingly, one or both contacts 46, 48 may be transparent or optically transmissive.

A semiconductor layer, e.g., a p-type semiconductor layer, is show between the electrical contact, e.g., the transparent or optically transmissive contact layer, 46 and the photoconductive layer (e.g., the p-type photoconductive layer) 26. In various implementations, this semiconductive layer 46 may be doped (e.g., p-doped or p+-doped), for example, to be conductive and/or to provide an electrical contact. Likewise, one or more semiconductor layers can be added elsewhere in the state to provide a conductive optical path or for other reasons.

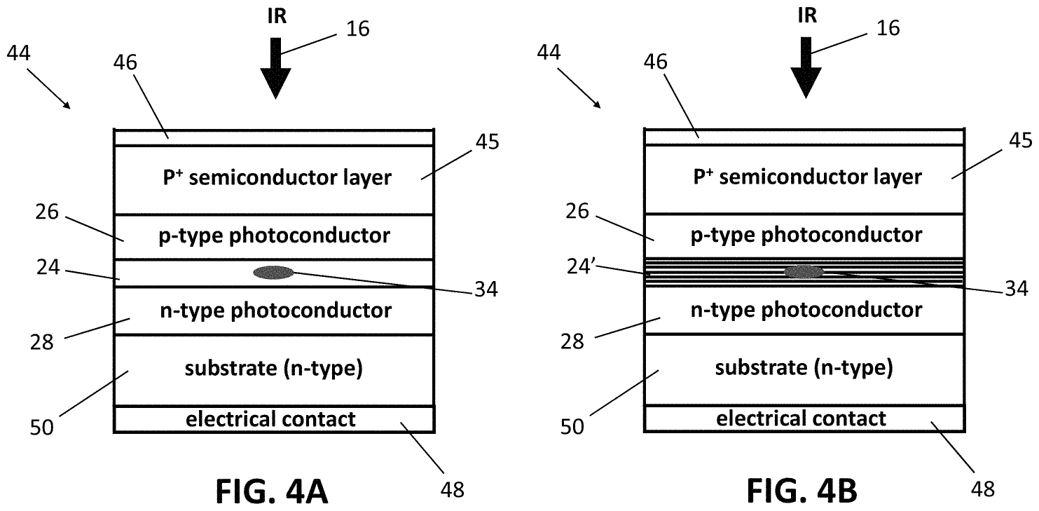

FIG. 3A shows the photoconductive layers 26, 28 and the quantum well 24 disposed on a substrate 50. This substrate 50 may comprise semiconductor material. The substrate may comprise, for example, aluminum nitride (AlN) or gallium nitride (GaN), although other materials can be used. In the example shown, the substrate 50 is n-doped and the n-type photoconductive layer 28 is closer to the substrate than the p-type photoconductive layer 26, however, other configurations are possible. In some implementations, the UV light emitter 44 may be integrated on a substrate 50 with other components such as possibly the optical pump 42. The laser diode could potentially be integrated on the chip possibly using an InGaN layer that is used to pump. The multilayer structure comprising for example a multilayer structure such as AlN/AlGaN/AlN/GaN/InGaN/GaN could be grown with the InGaN layer pumping the AlGaN laser where the AlN layers comprise p and n type photoconductor. FIG. 4A is a schematic cross-sectional view of the example UV light emitter 44 shown in FIG. 3A. The cross-section shown in FIG. 4A is orthogonal to the cross-section shown in FIG. 3A. UV light 34 is shown output from a light emission region of the emitter 44 shown in FIG. 4A.

As illustrated in FIG. 3B, in some implementations, a multiple quantum well 24′ is sandwiched between the first and second photoconductive layers 26, 28. The multiple quantum well 24′ may comprise, for example, alternating layers of material having different bandgaps to provide for a plurality of quantum wells separated by energy barriers. In various implementations, these materials comprise semiconductor materials such as AlGaN or InAlGaN with varying amounts of Al/Ga ratios. FIG. 4B is a schematic cross-sectional view of the example UV light emitter 44 shown in FIG. 3B. The cross-section shown in FIG. 4B is orthogonal to the cross-section shown in FIG. 3B. UV light 34 is shown output from a light emission region of the emitter 44 shown in FIG. 4B.

Different designs may comprise different materials. In some implementations, III-N material (a compound including an element from the III column of the periodic table and nitrogen) is used to produce the UV light 34 such as DUV light. For example, III-N material may be used as the laser gain medium for light sources comprising laser diodes. Similarly, III-N material may be used in LEDs to produce UV such as DUV light. In various implementations, for example, the quantum well 24 or multiple quantum well 24′ may comprise III-N material. Indium (In) or boron (B) could be incorporated into a III-N for use. In some cases, at least one of B or Al may be included to provide a sufficiently large bandgap. Example may include AlInGaN, BInGaN, AlBGaN.

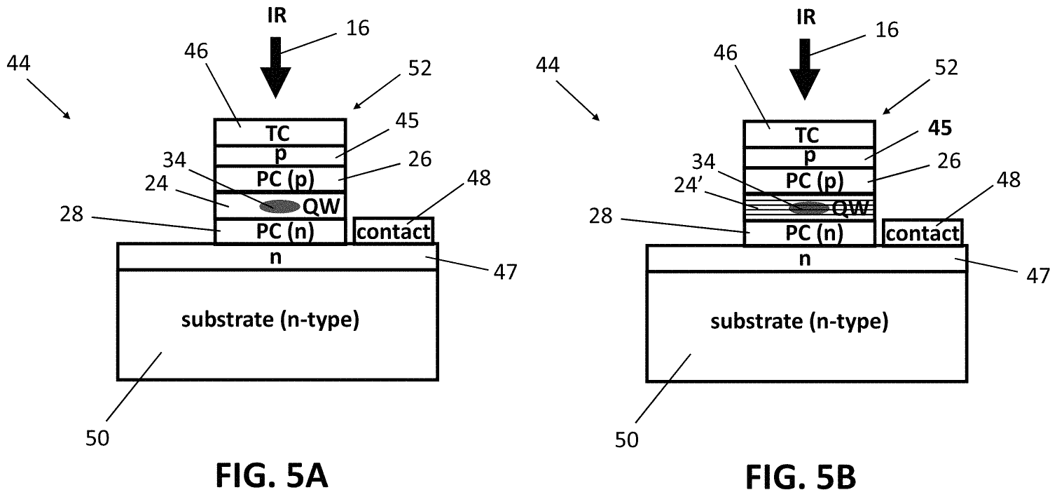

FIG. 5A is a schematic cross-sectional view of an example UV light emitter 44 similar to that shown in FIGS. 3A and 4A, however, wherein the quantum well 24 and photoconductive layers 26, 28 are formed in a mesa 52 formed on the semiconductor substrate 50. In the design shown in FIG. 5A, the electrical contact 48 is disposed on a semiconductor layer 47 between the substrate 50 and the photoconductive layer (e.g., the n-type photoconductor) 28. This semiconductor layer 47 may be doped to be conductive and/or to form a contact. For example, the semiconductor layer 47 may comprise an n+ semiconductor layer in some implementations although it should not be so limited. This configuration permits both electrical contacts 46, 48 to be on the same side of the substrate 50. Similarly, FIG. 5B shows a schematic cross-sectional view of an example UV light emitter 44 similar to that shown in FIGS. 3B and 4B, however, wherein the multiple quantum well 24′ and photoconductive layers 26, 28 are formed in a mesa 52 formed on the semiconductor substrate.

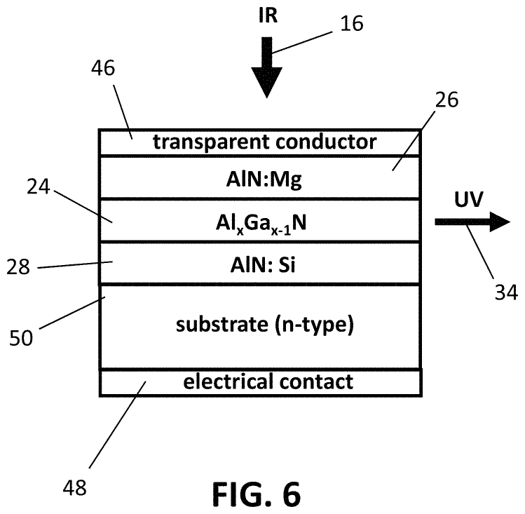

FIG. 6 shows an example UV light emitter 44 comprising a quantum well 24 comprising AlₓGaₓ₋₁N. The photoconductive layers 26, 28 comprise AlN. The p-type photoconductive layer 26 comprises aluminum nitride doped with magnesium, AlN:Mg. The n-type photoconductive layer 28 comprises aluminum nitride doped with silicon, AlN:Si. As shown in FIG. 6, one of the contacts 46 comprises a transparent or optically transmissive conductor while the other contact 48 may comprise a metal or a metal stack possibly to form an Ohmic contact. This contact 48 is closer to the n-type photoconductor layer 28 than the p-type photoconductor layer 26. Other configurations are possible. The AlₓGaₓ₋₁N quantum well 24 along with the AlN:Mg p-type photoconductive layer 26 and the AlN:Si n-type photoconductive layer 28 are supported by an n-type substrate 50. In some implementations, the substrate comprises aluminum nitride (AlN), although other materials may be used.

Other material systems may be employed. For example, AlGaInN may be used. Layers comprising various ratios of Al, Ga, and In can be used to provide the appropriate band gap and band line-up. Other materials and material systems may also be employed.

Any of or all of the quantum well 24 and the photoconductor layers 26, 28 can be included in a structure, such as a resonator or optical cavity, configured to enhance the output. For example, a light trapping architecture, utilizing the principle of total internal reflection (TIR) and/or whispering gallery modes can be used to address possible low absorption coefficient of the dopants. (See, for example, for some discussion of “Total Internal Reflective Photoconductive Switch” described in U.S. Pat. No. 10,530,362). TIR optoelectronic devices may comprise multiple semiconductor materials. Both TIR optoelectronic devices and whispering gallery modes structures are compatible with standard semiconductor fabrication techniques.

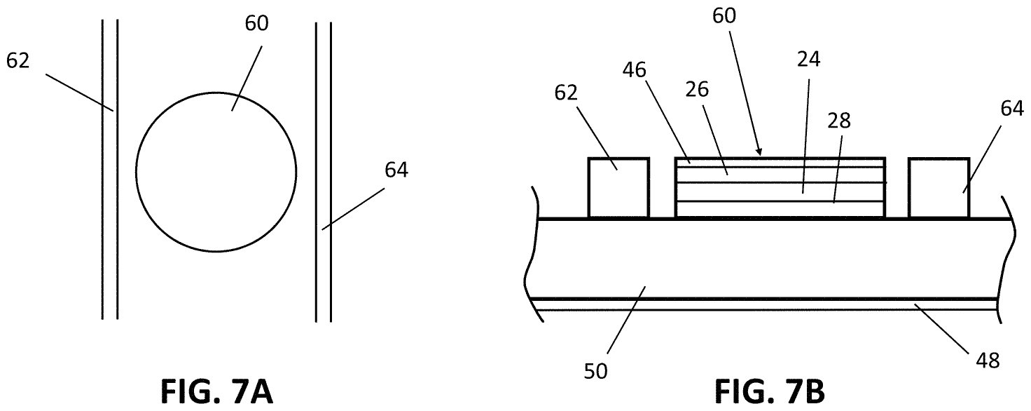

An example of a structure 60 that employs whispering gallery modes is shown in FIGS. 7A and 7B. In particular, FIGS. 7A and 7B show an optical resonator comprising a microdisc 60 that includes the quantum well 24 as well as the photoconductor layers 26, 28 therein. Also shown are input and output waveguides 62, 64 configured to couple light into and out of the microdisc 60. For example, the input waveguide 62 may receive sub-band gap light 16, such as infrared light, as pump light that is evanescently coupled into the microdisc 60 due to the close proximity of the input waveguide and the microdisc. The output waveguide 64 may receive UV light output 34 by the microdisc 60 possibly via evanescent coupling due to the close proximity of the output waveguide and the microdisc.

As shown in FIG. 7B the quantum well 24, as well as the photoconductor layers 26, 28 on opposite sides of the quantum well comprise layers in the microdisc 60. Similarly, in the example shown in FIG. 7B, the electrical contacts 47 and 48 are included on opposite sides of the quantum well 24 and photoconductors 26, 28. The first electrical contact 47 is on the top of the microdisc 60 and the second electrode 48 is on the other side of the substrate 50 as the microdisc. Other configurations, however, are possible. The microdisc 60 may comprise an optical resonator or optical cavity, which allows for multiple passes of pump light 16 through one or both of the photoconductive layers 26, 28. Similarly, the microdisc 60 may have a resonance enhancement of the UV light 34 emitted from the quantum well 24 as a result of multiple passes of the UV light with the microdisc optical resonator. The quantum well 24 and/or one or both of the photoconductive layers 26, 28 may be included in optical cavities, resonators, or other structures, for example, that may possibly enhance absorption of pump light 16 and/or output of the UV light 34 from the UV emitter 44. Accordingly, the geometry of the laser diode or LED may be such that incident sub-band gap light is trapped, providing high absorption thereof, using various schemes such as total internal reflection or a whispering gallery mode.

As illustrated in FIGS. 7A and 7B, said UV emitter 44 may comprise a waveguide device and/or may be integrated in a photonic integrated circuit. Likewise, in some implementations, the optical pump 42 may comprise a waveguide device and/or may be integrated in a photonic integrated circuit. In some designs both optical pump 42 and said UV emitter 44 may comprise a waveguide device and/or may be integrated in a photonic integrated circuit. In some implementations, the optical pump 42 and the UV emitter 44 are in optical communication via one or more waveguides, for example, that carry pump light 16 from the optical pump 42 to the UV emitter 44. Accordingly, in various designs, said first and second photoconductive layers 26, 28 and said at least one quantum well 24, 24′ are integrated in a photonic integrated circuit.

In some designs, the optical pump 42 and said UV emitter 44 may be included in a stack, for example, with the optical pump 42 stacked on the UV emitter 44 or vice versa. For example, an optical pump 42 may be disposed on top of a UV emitter 44 having a transparent or optically transmissive electrode 46 such as shown in FIG. 3 such that light can be directed from the optical pump 42 through the transparent or optically transmissive electrode 46 to one or both of the photoconductive layers 26, 28. Accordingly, the optical pump 42 may be disposed to direct pump light 16 at UV emitter 44 or one or more optical fibers may be used to couple light from the optical pump to the UV emitter. One or more optical elements may be disposed in the optical path from the optical pump 42 to the UV emitter 44, for example, to direct the pump light 16 to the UV emitter and/or to condition the light or otherwise.

Moreover, various devices, systems and methods described herein enable efficient production of UV light 34 such as UV laser light. In particular, UV laser diodes and UV light emitting diodes that output ultraviolet and possibly deep ultraviolet light are possible.

Although various examples of optical source that emit UV light are discussed above, the designs disclosed herein are not limited to UV emitters but can be employed for light sources that emit light at wavelengths other than ultraviolet wavelengths. Additionally, a wide variety of variations are possible. For example, additional layers such as semiconductor layers may be included, less layers may be included, layers may be rearrange or configured differently. Other variations are also possible.

### EXAMPLES

This disclosure provides various examples of devices, systems, and methods for outputting light such as UV and/or DUV light. These devices may include UV laser diodes and/or UV LEDs. Some such examples include but are not limited to the following enumerated examples.

### Examples—Part I

1. A light source for emitting ultraviolet (UV) light comprising:
a UV light emitter comprising:
   a first photoconductive layer;
   at least one quantum well having a band gap configured to emit ultraviolet light; and
   a second photoconductive layer;
at least one optical pump configured to direct pump light to said UV light emitter, said pump light having an energy less than the bandgap of said at least one quantum well, said pump light configured to increase the conductivity of electrons and holes in said first and second photoconductive layers such that said electrons and holes propagate to said at least one quantum well resulting in the emission of UV light.

2. The light source of Example 1, wherein said at least one quantum well is disposed between said first and second photoconductive layers.

3. The light source of Example 1 or 2, wherein said at least one optical pump comprises an infrared pump.

4. The light source of any of the examples above, wherein said at least one optical pump comprises an infrared laser.

5. The light source of any of the examples above, wherein said at least one optical pump comprises an infrared laser diode.

6. The light source of any of the examples above, wherein said first photoconductive layer, said second photoconductive layer, or both comprise semiconductor.

7. The light source of any of the examples above, wherein said first photoconductive layer, said second photoconductive layer, or both comprise III-N material.

8. The light source of any of the examples above, wherein said first photoconductive layer comprises semiconductor.

9. The light source of any of the examples above, wherein said first photoconductive layer comprises III-N material.

10. The light source of any of the examples above, wherein said second photoconductive layer comprises semiconductor.

11. The light source of any of the examples above, wherein said second photoconductive layer comprises III-N material.

12. The light source of any of the examples above, wherein said at least one quantum well comprises semiconductor.

13. The light source of any of the examples above, wherein said at least one quantum well comprises III-N material.

14. The light source of any of the examples above, wherein said first photoconductive layer, said second photoconductive layer, or both comprise aluminum nitride (AlN).

15. The light source of any of the examples above, wherein said first photoconductive layer and said second photoconductive layer comprise aluminum nitride (AlN).

16. The light source of any of the examples above, wherein said first photoconductive layer comprises aluminum nitride (AlN) that is doped with silicon (Si).

17. The light source of any of the examples above, wherein said second photoconductive layer comprises aluminum nitride (AlN) that is doped with magnesium (Mg).

18. The light source of any of the examples above, wherein said at least one quantum well comprises aluminum gallium nitride.

19. The light source of any of the examples above, wherein said at least one quantum well comprises a multiple quantum well.

20. The light source of any of the examples above, further comprising a transparent or optically transmissive conductor disposed with respect to said light source and said first or second photoconductive layer such that pump light from said optical pump passes through said transparent or optically transmissive conductor to said first or second photoconductive layer or both.

21. The light source of any of the examples above, wherein said light source comprises a light emitting diode (LED).

22. The light source of any of Examples 1-20, wherein said light source comprises a laser diode.

23. The light source of any of the examples above, wherein at least some of said electrons and holes combine in said at least one quantum well to produce said emission of UV light.

24. The light source of any of the examples above, wherein said first and second photoconductive layers and said at least one quantum well are integrated in a photonic integrated circuit.

25. The light source of any of the examples above, wherein said first and second photoconductive layers and said at least one quantum well are included in a total internal reflection structure.

26. The light source of any of the examples above, wherein said first and second photoconductive layers and said at least one quantum well are included in an optical resonator.

27. The light source of any of the examples above, wherein said first and second photoconductive layers and said at least one quantum well are included in a microdisc.

### Examples—Part II

1. A light source for emitting ultraviolet (UV) light comprising:
a UV light emitter comprising:
   a first photoconductive layer comprising semiconductor doped such that electrons are excited into a conduction band when exposed to infrared light;
   at least one quantum well configured to emit ultraviolet light; and
   a second photoconductive layer comprising semiconductor doped such that holes are excited into the valence band when exposed to infrared light; and
at least one optical pump configured to direct light to said UV light emitter such that electrons and holes are excited into said conduction band and said valence band, respectively, and at least some of said electrons and holes combine in said quantum well thereby producing UV light emission.

2. The light source of Example 1, wherein said at least one quantum well is disposed between said first and second photoconductive layers.

3. The light source of Example 1 or 2, wherein said at least one optical pump comprises an infrared pump.

4. The light source of any of the examples above, wherein said at least one optical pump comprises an infrared laser.

5. The light source of any of the examples above, wherein said at least one optical pump comprises an infrared laser diode.

6. The light source of any of the examples above, wherein said first photoconductive layer, said second photoconductive layer, or both comprise III-N material.

7. The light source of any of the examples above, wherein said first photoconductive layer comprises III-N material.

8. The light source of any of the examples above, wherein said second photoconductive layer comprises III-N material.

9. The light source of any of the examples above, wherein said at least one quantum well comprises semiconductor.

10. The light source of any of the examples above, wherein said at least one quantum well comprises III-N material.

11. The light source of any of the examples above, wherein said first photoconductive layer, said second photoconductive layer, or both comprise aluminum nitride (AlN).

12. The light source of any of the examples above, wherein said first photoconductive layer and said second photoconductive layer comprise aluminum nitride (AlN).

13. The light source of any of the examples above, wherein said first photoconductive layer comprises aluminum nitride (AlN) that is doped with silicon (Si).

14. The light source of any of the examples above, wherein said second photoconductive layer comprises aluminum nitride (AlN) that is doped with magnesium (Mg).

15. The light source of any of the examples above, wherein said at least one quantum well comprises aluminum gallium nitride.

16. The light source of any of the examples above, wherein said at least one quantum well comprises a multiple quantum well.

17. The light source of any of the examples above, further comprising a transparent or optically transmissive conductor disposed with respect to said light source and said first or second photoconductive layer such that pump light from said optical pump passes through said transparent or optically transmissive conductor to said first or second photoconductive layer or both.

18. The light source of any of the examples above, wherein said light source comprises a light emitting diode (LED).

19. The light source of any of Examples 1-17, wherein said light source comprises a laser diode.

20. The light source of any of the examples above, wherein said first and second photoconductive layers and said at least one quantum well are integrated in a photonic integrated circuit.

21. The light source of any of the examples above, wherein said first and second photoconductive layers and said at least one quantum well are included in a total internal reflection structure.

22. The light source of any of the examples above, wherein said first and second photoconductive layers and said at least one quantum well are included in an optical resonator.

23. The light source of any of the examples above, wherein said first and second photoconductive layers and said at least one quantum well are included in a microdisc.

### Examples—Part III

1. A light source for emitting ultraviolet (UV) light comprising:
a UV light emitter comprising:
   a first photoconductive layer;
   a multiple quantum well having band gaps configured to emit ultraviolet light; and
   a second photoconductive layer;
at least one optical pump configured to direct pump light to said UV light emitter, said pump light having an energy less than the bandgaps of said multiple quantum well, said pump light configured to increase the conductivity of electrons and holes in said first and second photoconductive layers such that said electrons and holes propagate to said multiple quantum well resulting in the emission of UV light.

2. The light source of Example 1, wherein said multiple quantum well is disposed between said first and second photoconductive layers.

3. The light source of Example 1 or 2, wherein said at least one optical pump comprises an infrared pump.

4. The light source of any of the examples above, wherein said at least one optical pump comprises an infrared laser.

5. The light source of any of the examples above, wherein said at least one optical pump comprises an infrared laser diode.

6. The light source of any of the examples above, wherein said first photoconductive layer, said second photoconductive layer, or both comprise semiconductor.

7. The light source of any of the examples above, wherein said first photoconductive layer, said second photoconductive layer, or both comprise III-N material.

8. The light source of any of the examples above, wherein said first photoconductive layer comprises semiconductor.

9. The light source of any of the examples above, wherein said first photoconductive layer comprises III-N material.

10. The light source of any of the examples above, wherein said second photoconductive layer comprises semiconductor.

11. The light source of any of the examples above, wherein said second photoconductive layer comprises III-N material.

12. The light source of any of the examples above, wherein said multiple quantum well comprises semiconductor.

13. The light source of any of the examples above, wherein said multiple quantum well comprises III-N material.

14. The light source of any of the examples above, wherein said first photoconductive layer, said second photoconductive layer, or both comprise aluminum nitride (AlN).

15. The light source of any of the examples above, wherein said first photoconductive layer and said second photoconductive layer comprise aluminum nitride (AlN).

16. The light source of any of the examples above, wherein said first photoconductive layer comprises aluminum nitride (AlN) that is doped with silicon (Si).

17. The light source of any of the examples above, wherein said second photoconductive layer comprises aluminum nitride (AlN) that is doped with magnesium (Mg).

18. The light source of any of the examples above, wherein said at least one quantum well comprises aluminum gallium nitride.

19. The light source of any of the examples above, further comprising a transparent or optically transmissive conductor disposed with respect to said light source and said first or second photoconductive layer such that pump light from said optical pump passes through said transparent or optically transmissive conductor to said first or second photoconductive layer or both.

20. The light source of any of the examples above, wherein said light source comprises a light emitting diode (LED).

21. The light source of any of Examples 1-19, wherein said light source comprises a laser diode.

22. The light source of any of the examples above, wherein at least some of said electrons and holes combine in said multiple quantum well to produce said emission of UV light.

23. The light source of any of the examples above, wherein said first and second photoconductive layers and said multiple quantum well are integrated in a photonic integrated circuit.

24. The light source of any of the examples above, wherein said first and second photoconductive layers and said multiple quantum well are included in a total internal reflection structure.

25. The light source of any of the examples above, wherein said first and second photoconductive layers and said multiple quantum well are included in an optical resonator.

26. The light source of any of the examples above, wherein said first and second photoconductive layers and said multiple quantum well are included in a microdisc.

### Examples—Part IV

1. A light source for emitting ultraviolet (UV) light comprising:
a UV light emitter comprising:
   a first photoconductive layer comprising semiconductor doped such that electrons are excited into a conduction band when exposed to infrared light;
   a multiple quantum well configured to emit ultraviolet light; and
   a second photoconductive layer comprising semiconductor doped such that holes are excited into the valence band when exposed to infrared light; and
at least one optical pump configured to direct light to said UV light emitter such that electrons and holes are excited into said conduction band and said valence band, respectively, and at least some of said electrons and holes combine in said multiple quantum well thereby producing UV light emission.

2. The light source of Example 1, wherein said multiple quantum well is disposed between said first and second photoconductive layers.

3. The light source of Example 1 or 2, wherein said at least one optical pump comprises an infrared pump.

4. The light source of any of the examples above, wherein said at least one optical pump comprises an infrared laser.

5. The light source of any of the examples above, wherein said at least one optical pump comprises an infrared laser diode.

6. The light source of any of the examples above, wherein said first photoconductive layer, said second photoconductive layer, or both comprise III-N material.

7. The light source of any of the examples above, wherein said first photoconductive layer comprises III-N material.

8. The light source of any of the examples above, wherein said second photoconductive layer comprises III-N material.

9. The light source of any of the examples above, wherein said multiple quantum well comprises semiconductor.

10. The light source of any of the examples above, wherein said multiple quantum well comprises III-N material.

11. The light source of any of the examples above, wherein said first photoconductive layer, said second photoconductive layer, or both comprise aluminum nitride (AlN).

12. The light source of any of the examples above, wherein said first photoconductive layer and said second photoconductive layer comprise aluminum nitride (AlN).

13. The light source of any of the examples above, wherein said first photoconductive layer comprises aluminum nitride (AlN) that is doped with silicon (Si).

14. The light source of any of the examples above, wherein said second photoconductive layer comprises aluminum nitride (AlN) that is doped with magnesium (Mg).

15. The light source of any of the examples above, wherein said multiple quantum well comprises aluminum gallium nitride.

16. The light source of any of the examples above, wherein said multiple quantum well comprises a multiple quantum well.

17. The light source of any of the examples above, further comprising a transparent or optically transmissive conductor disposed with respect to said light source and said first or second photoconductive layer such that pump light from said optical pump passes through said transparent or optically transmissive conductor to said first or second photoconductive layer or both.

18. The light source of any of the examples above, wherein said light source comprises a light emitting diode (LED).

19. The light source of any of Examples 1-17, wherein said light source comprises a laser diode.

20. The light source of any of the examples above, wherein said first and second photoconductive layers and said multiple quantum well are integrated in a photonic integrated circuit.

21. The light source of any of the examples above, wherein said first and second photoconductive layers and said multiple quantum well are included in a total internal reflection structure.

22. The light source of any of the examples above, wherein said first and second photoconductive layers and said multiple quantum well are included in an optical resonator.

23. The light source of any of the examples above, wherein said first and second photoconductive layers and said multiple quantum well are included in a microdisc.

### Examples—Part V

1. A light source for emitting light comprising:
a light emitter comprising:
   a first photoconductive layer;
   at least one quantum well having a band gap configured to emit ultraviolet light; and
   a second photoconductive layer;
at least one optical pump configured to direct pump light to said light emitter, said pump light having an energy less than the bandgap of said at least one quantum well, said pump light configured to increase the conductivity of electrons and holes in said first and second photoconductive layers such that said electrons and holes propagate to said at least one quantum well resulting in the emission of light.

2. The light source of Example 1, wherein said at least one quantum well is disposed between said first and second photoconductive layers.

3. The light source of Example 1 or 2, wherein said at least one optical pump comprises an infrared pump.

4. The light source of any of the examples above, wherein said at least one optical pump comprises an infrared laser.

5. The light source of any of the examples above, wherein said at least one optical pump comprises an infrared laser diode.

6. The light source of any of the examples above, wherein said first photoconductive layer, said second photoconductive layer, or both comprise III-N material.

7. The light source of any of the examples above, wherein said first photoconductive layer comprises III-N material.

8. The light source of any of the examples above, wherein said second photoconductive layer comprises III-N material.

9. The light source of any of the examples above, wherein said at least one quantum well comprises semiconductor.

10. The light source of any of the examples above, wherein said at least one quantum well comprises III-N material.

11. The light source of any of the examples above, wherein said first photoconductive layer, said second photoconductive layer, or both comprise aluminum nitride (AlN).

12. The light source of any of the examples above, wherein said first photoconductive layer and said second photoconductive layer comprise aluminum nitride (AlN).

13. The light source of any of the examples above, wherein said first photoconductive layer comprises aluminum nitride (AlN) that is doped with silicon (Si).

14. The light source of any of the examples above, wherein said second photoconductive layer comprises aluminum nitride (AlN) that is doped with magnesium (Mg).

15. The light source of any of the examples above, wherein said at least one quantum well comprises aluminum gallium nitride.

16. The light source of any of the examples above, wherein said at least one quantum well comprises a multiple quantum well.

17. The light source of any of the examples above, further comprising a transparent or optically transmissive conductor disposed with respect to said light source and said first or second photoconductive layer such that pump light from said optical pump passes through said transparent or optically transmissive conductor to said first or second photoconductive layer or both.

18. The light source of any of the examples above, wherein said light source comprises a light emitting diode (LED).

19. The light source of any of Examples 1-17, wherein said light source comprises a laser diode.

20. The light source of any of the examples above, wherein at least some of said electrons and holes combine in said at least one quantum well to produce said emission of UV light.

21. The light source of any of the examples above, wherein said first and second photoconductive layers and said at least one quantum well are integrated in a photonic integrated circuit.

22. The light source of any of the examples above, wherein said first and second photoconductive layers and said at least one quantum well are included in a total internal reflection structure.

23. The light source of any of the examples above, wherein said first and second photoconductive layers and said at least one quantum well are included in an optical resonator.

24. The light source of any of the examples above, wherein said first and second photoconductive layers and said at least one quantum well are included in a microdisc.

### Examples—Part VI

1. A light source for emitting light comprising:
a light emitter comprising:
   a first photoconductive layer comprising semiconductor doped such that electrons are excited into a conduction band when exposed to light;
   at lease one quantum well configured to emit light; and
   a second photoconductive layer comprising semiconductor doped such that holes are excited into the valence band when exposed to light; and
at least one optical pump configured to direct light to said light emitter such that electrons and holes are excited into said conduction band and said valence band, respectively, and at least some of said electrons and holes combine in said at least one quantum well thereby producing light emission.

2. The light source of Example 1, wherein said at least one quantum well is disposed between said first and second photoconductive layers.

3. The light source of Example 1 or 2, wherein said at least one optical pump comprises an infrared pump.

4. The light source of any of the examples above, wherein said at least one optical pump comprises an infrared laser.

5. The light source of any of the examples above, wherein said at least one optical pump comprises an infrared laser diode.

6. The light source of any of the examples above, wherein said first photoconductive layer, said second photoconductive layer, or both comprise III-N material.

7. The light source of any of the examples above, wherein said first photoconductive layer comprises III-N material.

8. The light source of any of the examples above, wherein said second photoconductive layer comprises III-N material.

9. The light source of any of the examples above, wherein said at least one quantum well comprises semiconductor.

10. The light source of any of the examples above, wherein said at least one quantum well comprises III-N material.

11. The light source of any of the examples above, wherein said first photoconductive layer, said second photoconductive layer, or both comprise aluminum nitride (AlN).

12. The light source of any of the examples above, wherein said first photoconductive layer and said second photoconductive layer comprise aluminum nitride (AlN).

13. The light source of any of the examples above, wherein said first photoconductive layer comprises aluminum nitride (AlN) that is doped with silicon (Si).

14. The light source of any of the examples above, wherein said second photoconductive layer comprises aluminum nitride (AlN) that is doped with magnesium (Mg).

15. The light source of any of the examples above, wherein said at least one quantum well comprises aluminum gallium nitride.

16. The light source of any of the examples above, wherein said at least one quantum well comprises a multiple quantum well.

17. The light source of any of the examples above, further comprising a transparent or optically transmissive conductor disposed with respect to said light source and said first or second photoconductive layer such that pump light from said optical pump passes through said transparent or optically transmissive conductor to said first or second photoconductive layer or both.

18. The light source of any of the examples above, wherein said light source comprises a light emitting diode (LED).

19. The light source of any of Examples 1-17, wherein said light source comprises a laser diode.

20. The light source of any of the examples above, wherein said first and second photoconductive layers and said at least one quantum well are integrated in a photonic integrated circuit.

21. The light source of any of the examples above, wherein said first and second photoconductive layers and said at least one quantum well are included in a total internal reflection structure.

22. The light source of any of the examples above, wherein said first and second photoconductive layers and said at least one quantum well are included in an optical resonator.

23. The light source of any of the examples above, wherein said first and second photoconductive layers and said at least one quantum well are included in a microdisc.

### Examples—Part VII

1. A light source for emitting ultraviolet (UV) light comprising:
a UV light emitter comprising:
   at least one photoconductive layer; and
   at least one quantum well having a band gap configured to emit ultraviolet light;
at least one optical pump configured to direct pump light to said UV light emitter, said pump light having an energy less than the bandgap of said at least one quantum well, said pump light configured to increase the conductivity of electrons or holes in said at least one photoconductive layer such that said electrons and/or holes propagate to said at least one quantum well resulting in the emission of UV light.

2. The light source of Example 1, wherein said at least one optical pump comprises an infrared pump.

3. The light source of any of Example 1 or 2, wherein said at least one optical pump comprises an infrared laser.

4. The light source of any of the examples above, wherein said at least one optical pump comprises an infrared laser diode.

5. The light source of any of the examples above, wherein said at least one photoconductive layer comprises semiconductor.

6. The light source of any of the examples above, wherein said at least one photoconductive layer comprises III-N material.

7. The light source of any of the examples above, wherein said at least one quantum well comprises semiconductor.

8. The light source of any of the examples above, wherein said at least one quantum well comprises III-N material.

9. The light source of any of the examples above, wherein said at least one photoconductive layer comprises aluminum nitride (AlN).

10. The light source of any of the examples above, wherein said at least one photoconductive layer comprises aluminum nitride (AlN) that is doped with silicon (Si).

11. The light source of any of the examples above, wherein said at least one photoconductive layer comprises aluminum nitride (AlN) that is doped with magnesium (Mg).

12. The light source of any of the examples above, wherein said at least one quantum well comprises aluminum gallium nitride.

13. The light source of any of the examples above, further comprising a transparent or optically transmissive conductor disposed with respect to said light source and said at least one photoconductive layer such that pump light from said optical pump passes through said transparent or optically transmissive conductor to said at least one photoconductive layer.

14. The light source of any of the examples above, wherein said light source comprises a light emitting diode (LED).

15. The light source of any of Examples 1-13, wherein said light source comprises a laser diode.

16. The light source of any of the examples above, wherein said at least one quantum well comprises a multiple quantum well.

17. The light source of any of the examples above, wherein at least some of said electrons and holes combine in said at least one quantum well to produce said emission of UV light.

18. The light source of any of the examples above, wherein said at least one photoconductive layer and said at least one quantum well are integrated in a photonic integrated circuit.

19. The light source of any of the examples above, wherein said at least one photoconductive layer and said at least one quantum well are included in a total internal reflection structure.

20. The light source of any of the examples above, wherein said at least one photoconductive layer and said at least one quantum well are included in an optical resonator.

21. The light source of any of the examples above, wherein said at least one photoconductive layer and said at least one quantum well are included in a microdisc.

Although the description above contains many details and specifics, these should not be construed as limiting the scope of the invention but as merely providing illustrations of some of the presently preferred embodiments of this invention. Other implementations, enhancements and variations can be made based on what is described and illustrated in this patent document. The features of the embodiments described herein may be combined in all possible combinations of methods, apparatus, modules, systems, and computer program products. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination. Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described above should not be understood as requiring such separation in all embodiments.

Therefore, it will be appreciated that the scope of the present invention fully encompasses other embodiments which may become obvious to those skilled in the art. In the claims, reference to an element in the singular is not intended to mean “one and only one” unless explicitly so stated, but rather “one or more.” All structural and functional equivalents to the elements of the above-described preferred embodiment that are known to those of ordinary skill in the art are expressly incorporated herein by reference and are intended to be encompassed by the present claims. Moreover, it is not necessary for a device to address each and every problem sought to be solved by the present invention, for it to be encompassed by the present claims. Furthermore, no element or component in the present disclosure is intended to be dedicated to the public regardless of whether the element or component is explicitly recited in the claims. No claim element herein is to be construed under the provisions of 35 U.S.C. 112, sixth paragraph, unless the element is expressly recited using the phrase “means for.”

What is claimed is:

1. A light source for emitting ultraviolet (UV) light comprising:
a UV light emitter comprising:
a first photoconductive layer;
at least one quantum well having a band gap configured to emit ultraviolet light; and
a second photoconductive layer;
at least one optical pump configured to direct pump light to said UV light emitter, said pump light having an energy less than the bandgap of said at least one quantum well, said pump light configured to increase the conductivity of electrons and holes in said first and second photoconductive layers such that said electrons and holes propagate to said at least one quantum well resulting in the emission of UV light.

2. The light source of claim 1, wherein said at least one quantum well is disposed between said first and second photoconductive layers.

3. The light source of claim 1, wherein said at least one optical pump comprises an infrared pump.

4. The light source of claim 1, wherein said first photoconductive layer, said second photoconductive layer, or both comprise semiconductor.

5. The light source of claim 1, wherein said first photoconductive layer, said second photoconductive layer, or both comprise III-N material.

6. The light source of claim 1, wherein said at least one quantum well comprises semiconductor.

7. The light source of claim 1, wherein said at least one quantum well comprises III-N material.

8. The light source of claim 1, wherein said first photoconductive layer, said second photoconductive layer, or both comprise aluminum nitride (AlN).

9. The light source of claim 1, wherein said first photoconductive layer and said second photoconductive layer comprise aluminum nitride (AlN).

10. The light source of claim 1, wherein said first photoconductive layer comprises aluminum nitride (AlN) that is doped with silicon (Si).

11. The light source of claim 1, wherein said second photoconductive layer comprises aluminum nitride (AlN) that is doped with magnesium (Mg).

12. The light source of claim 1, wherein said at least one quantum well comprises aluminum gallium nitride.

13. The light source of claim 1, wherein said at least one quantum well comprises a multiple quantum well.

14. The light source of claim 1, further comprising a transparent or optically transmissive conductor disposed with respect to said light source and said first or second photoconductive layer such that pump light from said optical pump passes through said transparent or optically transmissive conductor to said first or second photoconductive layers or both.

15. The light source of claim 1, wherein said light source comprises a light emitting diode (LED) or laser diode.

16. The light source of claim 1, wherein at least some of said electrons and holes combine in said at least one quantum well to produce said emission of UV light.

17. The light source of claim 1, wherein said first and second photoconductive layers and said at least one quantum well are integrated in a photonic integrated circuit.

18. The light source of claim 1, wherein said first and second photoconductive layers and said at least one quantum well are included in a total internal reflection structure.

19. The light source of claim 1, wherein said first and second photoconductive layers and said at least one quantum well are included in an optical resonator.

20. The light source of claim 1, wherein said first and second photoconductive layers and said at least one quantum well are included in a microdisc.
